(19) United States
(12) Patent Application Publication
(10) Pub. No.: US 2001/0001733 A1
(43) Pub. Date: May 24, 2001

(54) IMPROVED METHOD FOR SELECTIVELY ETCHING A SEMICONDUCTOR DEVICE

(76) Inventor: JAMES KENT NAYLOR, KAYSVILLE, UT (US)

Correspondence Address: CRAWFORD PLLC, 1270 NORTHLAND DRIVE, SUITE 390, MENDOTA HEIGHTS, MN, 55120

(21) Appl. No.: 09/312,738

(22) Filed: May 14, 1999

(51) Int. Cl. H01L 21/302

(52) U.S. Cl. 438/689

(57) ABSTRACT

According to an example embodiment, the present invention is directed to a method for manufacturing a semiconductor device. The device comprises a light-reflective layer and an anti-reflective coating layer over the light-reflective layer. A material is located over the anti-reflective coating layer. The semiconductor is selectively etched using a non-polymerizing oxygen-rich fluorocarbon chemistry. By using an oxygen-rich fluorocarbon chemistry, the use of a polymerizing etchant is eliminated, making the manufacture of such devices simpler.

### FIELD OF THE INVENTION

The present invention relates generally to semiconductor devices and their fabrication and, more particularly, to an improved method for selectively etching a semiconductor device.

### BACKGROUND OF THE INVENTION

The electronics industry continues to rely upon advances in semiconductor technology to realize higher-functioning devices in more compact areas. For many applications, realizing higher-functioning devices requires integrating a large number of electronic devices into a single silicon wafer. In addition, many of the individual devices within the wafer are being manufactured with smaller physical dimensions. As the number of electronic devices per given area of the silicon wafer increases, and as the size of the individual devices decreases, the manufacturing process becomes more difficult.

A large variety of semiconductor devices have been manufactured having various applications in numerous disciplines. Such silicon-based semiconductor devices often include metal-oxide-semiconductor (MOS) transistors, such as p-channel MOS (PMOS), n-channel MOS (NMOS) and complimentary MOS (CMOS) transistors, bipolar transistors, and BiCMOS transistors.

Such devices often include metal conductors which are separated by an insulator, such as an oxide. In the manufacture of such devices it is sometimes necessary to create patterns showing the arrangement of the metal conductors within the device. When the required distances between metal conductor lines and spaces are less than about 0.4 microns, deep ultraviolet (DUV) photolithography is typically used to enable patterning such tightly spaced metal lines. DUV photolithography uses ultraviolet light in about the 248 nanometer range. This photolithography involves the application of a thin film of photoresist, such as a photo-sensitive polymer, for example, to a layer in a semiconductor device. A mask containing clear and opaque regions that defines a pattern to be created in the photoresist layer is then formed on the photoresist.

The masked photoresist is then exposed to light, such as ultraviolet light. Depending upon the material used, the areas in the photoresist exposed to the light are made either soluble or insoluble in a specific solvent known as a developer. When the exposed regions are soluble, the exposed regions are dissolved by the developer, the mask's positive image is created in the resist, and the result is termed a positive resist. When the exposed regions become insoluble, the non-exposed regions are dissolved by the developer, leaving a negative image of the mask in the resist, resulting in a negative resist.

Many commercially-available DUV resists rely on chemically-amplified resist chemistry. In this approach, DUV exposure causes a component known as a photoacid generator (AG) to decompose to an acidic species. For positive DUV resists, post-exposure baking (PEB) catalyzes the acid to react to the surrounding polymer which converts the surrounding polymer from base insoluble to soluble. A potential problem with lithography resists arises when contaminants in the surrounding air are absorbed onto the surface of the resist and neutralize the acid at the surface. When this occurs, the resist at the surface remains insoluble to base even though the underlying resist is soluble. The insoluble surface hinders photolithography. The performance of such photolithography is enhanced by reducing or removing the contaminants, and increasing the purity of the photoresist material. A method of increasing the purity of the photoresist material, for example, includes ashing. Ashing removes the insoluble surface material without adversely affecting the underlying resist.

Another potential problem with lithography arises because, at lower wavelengths characteristic of DUV lithography, metals are very reflective. A bottom antireflective coating (BARC) layer is typically used on top of the metal to minimize the deleterious effects of reflection. A very effective BARC material is silicon oxynitride (SiON), deposited by plasma enhanced chemical vapor deposition (PECVD) on top of the metal just before metal patterning. After etching the SiON/metal stack, SiON remains on top of the metal lines.

It is necessary at times to create electrical connections between metal lines within a semiconductor device. Inter-metal oxide (IMO), often formed between layers of metal, acts as an insulator between the metal lines. In order to make electrical contact between layers of metal, a hole is formed by etching through the oxide and down to the underlying layer of metal. When SiON is used as a BARC layer on the underlying metal, the etching process must also etch through the SiON to allow an electrical contact to be made to the metal. It would be desirable to selectively etch (etching selected material while other non-selected material is not etched) the SiON (as the bottom anti-reflective layer) with respect to the surrounding oxide or with respect to the subsequent metal.

Typically, SiON is plasma etched using conventional fluorocarbon chemistries such as CHF₃, CF₄, or C₄F₈. These chemistries etch silicon oxide films effectively. Selectivity to underlying films such as silicon or TiN is achieved using a polymerizing mechanism. The fluorocarbon chemistry deposits a polymer coating such that oxygen-containing films are preferentially etched when the oxygen is released and thereby locally thinning the polymer coating.

For many applications, the polymerizing mechanism has been a necessary additional process for such selective etching of SiON. This additional process adds complexity and cost to the etching of semiconductor devices.

### SUMMARY OF THE INVENTION

The present invention improves the selective etching of semiconductor devices by methods eliminating the need for a polymerizing mechanism, thereby facilitating the manufacture of such devices. The present invention is exemplified in a number of implementations and applications, some of which are summarized below. According to an example embodiment, the present invention is directed to a method for manufacturing a semiconductor device. The semiconductor device includes a light reflective layer, an anti-reflective coating layer over the light-reflective layer, and a material over the anti-reflective coating layer. The semiconductor is selectively etched using a non-polymerizing oxygen-rich fluorocarbon chemistry.

According to another example embodiment, the present invention is directed to a method for manufacturing a semiconductor device. The semiconductor device includes a light reflective layer, an anti-reflective coating layer over the light-reflective layer, a material over the anti-reflective coating layer, and a photoresist layer. The photoresist layer and the material over the anti-reflective coating layer are etched and the antireflective coating layer is exposed. A non-polymerizing oxygen-rich fluorocarbon chemistry is used to ash the resist and selectively etch the anti-reflective layer.

The above summary of the present invention is not intended to describe each illustrated embodiment or every implementation of the present invention. The figures and detailed description which follow more particularly exemplify these embodiments.

### BRIEF DESCRIPTION OF THE DRAWINGS

The invention may be more completely understood in consideration of the following detailed description in connection with the accompanying drawings, in which:

FIG. 1 is a cross-sectional view of a portion of a semiconductor device, according to an example embodiment of the present invention;

FIG. 2 is a cross-sectional view of a portion of a semiconductor device, according to another example embodiment of the present invention, wherein a photoresist layer and an oxide layer have been etched; and

FIG. 3 is a cross-sectional view of a portion of a semiconductor device, according to still another example embodiment of the present invention, wherein a photoresist layer, an oxide layer, and an anti-reflective coating layer have been etched.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The present invention is believed to be applicable to a variety of different types of semiconductor devices, and the invention has been found to be particularly suited for devices requiring or benefiting from deep ultraviolet (DUV) photolithography. While the present invention is not necessarily limited to such devices, various aspects of the invention may be appreciated through a discussion of various examples in this context.

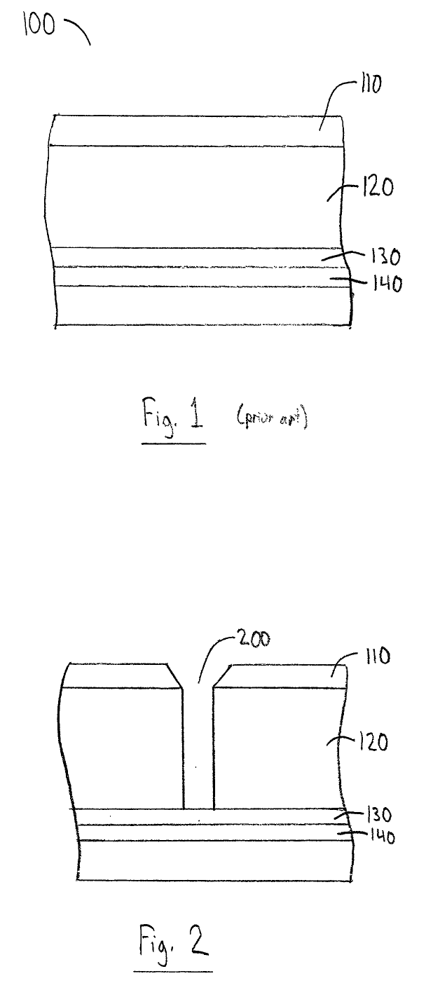

In one example embodiment, the present invention is directed to a method for manufacturing a semiconductor device. Referring to FIG. 1, for example, the semiconductor device includes a light-reflective layer 140, an anti-reflective coating layer 130 over the light-reflective layer 140, and material 120 over the anti-reflective coating 130. A non-polymerizing etchant is used to etch through the layer 130 of the semiconductor device as shown in FIG. 3. By using a non-polymerizing etchant, this embodiment abandons the polymerizing mechanism described herein and is more effective for selectively etching the anti-reflective film without etching any of the material over the anti-reflective film.

As examples, the light-reflective layer 140 may include metal, such as TiN, and the anti-reflective coating layer 130 may include SiON. In addition, the material 120 located over the anti-reflective coating layer 130 may include oxide, and the non-polymerizing etchant may include a non-polymerizing oxygen-rich fluorocarbon substance. A path through the anti-reflective coating layer 130 is selectively etched using, for example, a relatively small amount of CHF₃ and an abundance of oxygen. For instance, the path may be etched using CHF₃ supplied at a rate of about 5 ccm, and using oxygen supplied at a rate of about 45 ccm. In another example embodiment, a path is formed without etching the light-reflective layer 140. In addition, a path may be formed without etching the material 120 over the anti-reflective coating layer. In still another example embodiment, the path is etched using low power. For instance, etching the path may include using an upper electrode and a lower electrode, wherein the upper electrode is set at about 200 watts, and wherein the lower electrode is set at about 100 watts.

In another example embodiment, the semiconductor device includes a photoresist layer. As discussed at the outset hereof, the photoresist layer is used to enable patterning of characteristics including metal lines and spaces in the semiconductor device. The photoresist layer is ashed while the semiconductor is selectively etched using a non-polymerizing oxygen-rich fluorocarbon substance as an etchant. In this example embodiment, the ashing of the photoresist layer removes some or all of the photoresist without adversely affecting the underlying oxide. Ashing the photoresist enhances the performance of photolithography by reducing or removing the need for a separate ashing step or tool.

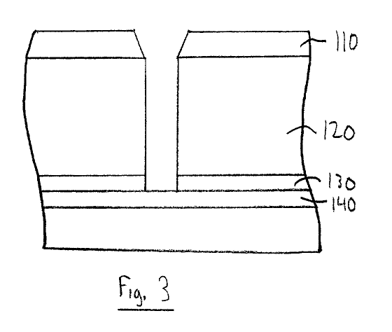

According to yet another example embodiment, and referring to FIG. 1, the present invention comprises a method for manufacturing a semiconductor device, wherein the semiconductor device includes a light-reflective layer 140 comprising TiN, an anti-reflective coating layer 130 comprising SiON, an insulator material layer 120 comprising oxide, and a photoresist layer 110 over the oxide. Referring to FIG. 2, the insulator layer 120 is etched, and the anti-reflective coating layer 130 is exposed. A non-polymerizing oxygen-rich fluorocarbon substance is used and the anti-reflective coating layer 130 is etched, while leaving the light-reflective layer 140 and the insulator material layer 120 intact.

While the present invention has been described with reference to several particular example embodiments, those skilled in the art will recognize that many changes may be made thereto without departing from the spirit and scope of the present invention, which is set forth in the following claims.

What is claimed is:

1. A method for manufacturing a semiconductor device, comprising: forming a light reflective layer, an anti-reflective coating layer over the light-reflective layer, and a material over the anti-reflective coating layer; and using a non-polymerizing oxygen-rich fluorocarbon chemistry to selectively etch the anti-reflective coating layer.

2. A method for manufacturing, according to claim 1, wherein the anti-reflective coating layer is selectively etched with respect to the material over the anti-reflective coating layer.

3. A method for manufacturing, according to claim 1, wherein the anti-reflective coating layer is selectively etched with respect to the light reflective layer.

4. The method of claim 1, wherein the oxygen rich fluorocarbon chemistry includes CHF₃.

5. The method of claim 1, wherein the oxygen rich fluorocarbon chemistry includes a relatively large amount of oxygen and a relatively small amount of CHF₃.

6. The method of claim 1, wherein the oxygen rich fluorocarbon chemistry includes about 45 ccm of oxygen, and about 5 ccm of CHF₃.

7. The method of claim 1, wherein selectively etching the semiconductor device includes etching at low power.

8. The method of claim 1, wherein selectively etching the semiconductor device includes the use of an upper electrode and a lower electrode, wherein the upper electrode is at a power setting of about 200 watts, and the lower electrode is at a power setting of about 100 watts.

9. The method of claim 1, wherein the semiconductor further comprises a photoresist layer, and wherein a significant amount of the resist is ashed while selectively etching the anti-reflective coating layer.

10. The method of claim 1, wherein the anti-reflective coating layer includes SiON, and wherein etching the anti-reflective coating layer includes etching the SiON.

11. The method of claim 1, wherein the light-reflective layer includes TiN, and wherein etching the anti-reflective coating layer leaves the TiN intact.

12. The method of claim 1, wherein the material over the anti-reflective coating layer includes oxide, and wherein etching the anti-reflective coating layer does not include etching the oxide.

13. The method of claim 1, wherein the material over the anti-reflective coating layer includes oxide, wherein the light-reflective layer includes a metal film, and wherein selectively etching the anti-reflective coating layer does not include etching the oxide or the metal film.

14. A method for manufacturing a semiconductor device, comprising: forming a light reflective layer, an anti-reflective coating layer over the light-reflective layer, and a material over the anti-reflective coating layer;
etching material over the anti-reflective coating layer and exposing the antireflective coating layer; and
using a non-polymerizing oxygen-rich fluorocarbon chemistry to selectively etch the anti-reflective coating layer.

15. A method for manufacturing a semiconductor device, according to claim 14, the semiconductor device further including a photoresist layer over the material over the anti-reflective coating layer, wherein etching material over the anti-reflective coating layer includes etching the resist, the method further comprising ashing the resist.

16. A method for manufacturing a semiconductor device, according to claim 14, wherein the light reflective layer remains intact.

17. A method for manufacturing a semiconductor device, according to claim 14, wherein the material over the anti-reflective layer remains intact during the etching of the anti-reflective coating layer.

18. A method for manufacturing a semiconductor device, wherein the semiconductor device includes a light reflective layer, an anti-reflective coating layer over the light-reflective layer, and a material over the anti-reflective coating layer, the method comprising:
using non-polymerizing means to selectively etch the anti-reflective coating layer with respect to the light-reflective layer and the material over the anti-reflective coating layer.

19. A semiconductor device manufactured according to claim 18.

20. A semiconductor device manufactured according to claim 1.
